(19) United States
(12) Patent Application Publication
(10) Pub. No.: US 2025/0232963 A1
(43) Pub. Date: Jul. 17, 2025

(54) Substrate Processing Apparatus

(71) Applicant: Tokyo Electron Limited, Tokyo (JP)

(72) Inventors: Motoi YAMAGATA, Tokyo (JP); Hiroshi SONE, Tokyo (JP); Naoya FUKUDA, Tokyo (JP)

(21) Appl. No.: 19/012,282

(22) Filed: Jan. 7, 2025

(30) Foreign Application Priority Data
Jan. 17, 2024 (JP) 2024-004950

(51) Int. Cl. H01J 37/32

(52) U.S. Cl. CPC H01J 37/32724; H01J 2237/002; H01J 2237/20214

(57) ABSTRACT

There is a substrate processing apparatus comprising: a processing chamber; a placing table having a first contact surface on an opposite side to a placing surface on which a substrate is placed; a freezing device having a second contact surface and configured to cool the placing table; a rotation device configured to rotate the placing table; a lifting device configured to raise and lower the freezing device to bring the first contact surface and the second contact surface into contact with each other or separate the first contact surface and the second contact surface; a heat transfer gas supply space including the first contact surface of the placing table and the second contact surface of the freezing device and isolated from an inner space of the processing chamber; and a gas inlet port that supplies a heat transfer gas to the heat transfer gas supply space.

### CROSS-REFERENCE TO RELATED APPLICATIONS

This application claims priority to Japanese Patent Application No. 2024-004950 filed on Jan. 17, 2024, the entire contents of which are incorporated herein by reference.

### TECHNICAL FIELD

The present disclosure relates to a substrate processing apparatus.

### BACKGROUND

Japanese Patent Publication No. 6559347 discloses a holding device capable of rotatably holding an object to be processed in a vacuum chamber during cooling of the object to be processed. The holding device includes a stage on which the object to be processed is placed, a rotating driving device that rotatably supports the stage, and a cooling device that cools the stage. A stage surface side on which the object to be processed is placed is disposed to face upward. The rotating driving device, includes: a tubular rotation shaft member penetrating through a wall surface of the vacuum chamber via a vacuum seal; a connecting member that connects an upper end portion of the rotation shaft member and a bottom surface of the stage such that a space is defined under the stage, and a driving motor that rotationally drives the rotation shaft member. The cooling device includes: a cooling panel disposed in the space under the stage to face the bottom surface of the stage via a gap; a heat transmitting shaft member inserted into the rotation shaft member and in contact with a bottom surface of the cooling panel; and a refrigerator for cooling the heat transmitting shaft member.

### SUMMARY

One aspect of the present disclosure provides a substrate processing apparatus for appropriately cooling a rotatable placing table.

In accordance with an exemplary embodiment of the present disclosure, there is a substrate processing apparatus comprising: a processing chamber; a placing table disposed in the processing chamber and having a first contact surface on an opposite side to a placing surface on which a substrate is placed; a freezing device having a second contact surface and configured to cool the placing table; a rotation device configured to rotate the placing table; a lifting device configured to raise and lower the freezing device to bring the first contact surface and the second contact surface into contact with each other or separate the first contact surface and the second contact surface from each other; a heat transfer gas supply space including the first contact surface of the placing table and the second contact surface of the freezing device and isolated from an inner space of the processing chamber; and a gas inlet port that supplies a heat transfer gas to the heat transfer gas supply space.

### BRIEF DESCRIPTION OF THE DRAWINGS

FIG. 1 is a cross-sectional view showing an example of a configuration of a substrate processing apparatus according to an embodiment during rotation of a placing table.

FIG. 2 is a cross-sectional view showing an example of a configuration of a substrate processing apparatus according to an embodiment during contact cooling of a placing table.

FIG. 3 shows an example of a cross-sectional view of a slip ring.

FIG. 4 shows an example of a cross-sectional view explaining a structure for cooling a power supply rod and a conductive bearing.

### DETAILED DESCRIPTION

Hereinafter, an embodiment of the present disclosure will be described in detail with reference to the accompanying drawings. Like reference numerals will be given to like or corresponding parts throughout the drawings, and redundant description thereof may be omitted.

### <Substrate Processing Apparatus 1>

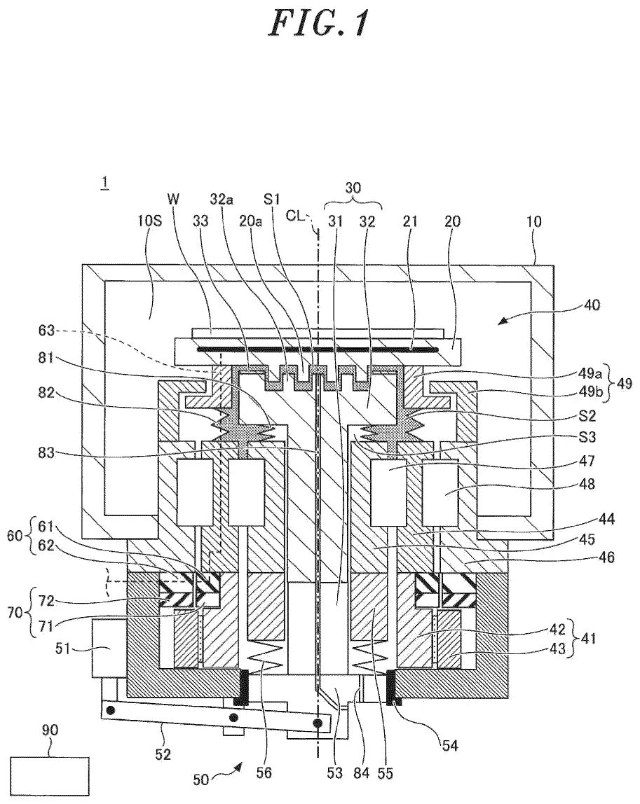

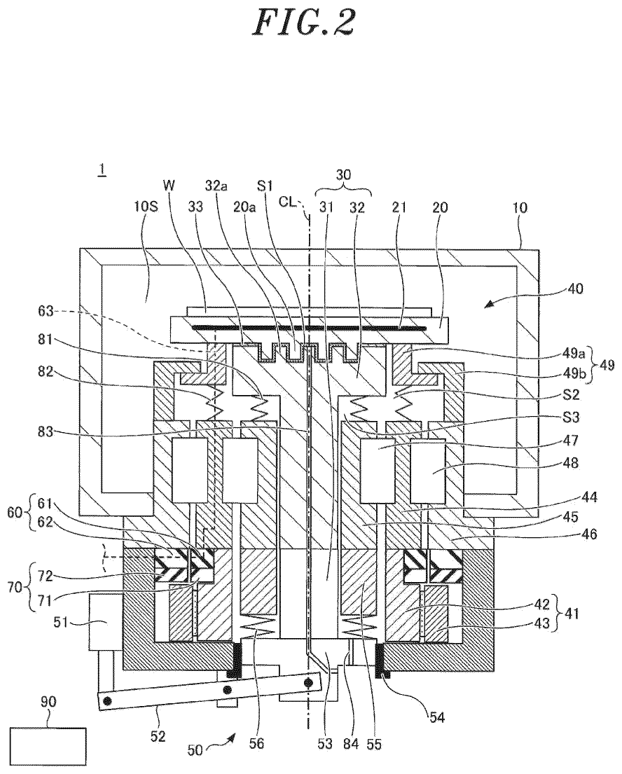

An example of a substrate processing apparatus 1 according to an embodiment will be described with reference to FIGS. 1 and 2. FIG. 1 is a cross-sectional view showing an example of a configuration of the substrate processing apparatus 1 according to an embodiment during rotation of a placing table 20. FIG. 2 is a cross-sectional view showing an example of a configuration of the substrate processing apparatus 1 according to an embodiment during contact cooling of the placing table 20.

The substrate processing apparatus 1 may be, for example, a substrate processing apparatus (e.g., a chemical vapor deposition (CVD) apparatus, an atomic layer deposition (ALD) apparatus, or the like) that supplies a processing gas into a processing chamber 10 and performs desired processing (e.g., film formation or the like) on a substrate W. The substrate processing apparatus 1 may also be, for example, a substrate processing apparatus (e.g., a physical vapor deposition (PVD) apparatus or the like) that supplies a processing gas into the processing chamber 10 and sputters a target disposed in the processing chamber 10 to perform desired processing (e.g., film formation or the like) on a substrate W.

The substrate processing apparatus 1 includes the processing chamber 10, a placing table 20 on which a substrate W is placed in the processing chamber 10, a freezing device 30, a rotation device 40 for rotating the placing table 20, and a lifting device 50 for raising and lowering the freezing device 30. The substrate processing apparatus 1 further includes a power supply rod 63 for supplying a power to an electrode 21 of the rotating placing table 20. The substrate processing apparatus 1 further includes a cooling mechanism 70 for cooling a power supply rod 63. The substrate processing apparatus 1 further includes a controller 90 for controlling various devices such as the freezing device 30, the rotation device 40, and the lifting device 50.

The processing chamber 10 forms an inner space 10S. The processing chamber 10 is configured such that a pressure in the inner space 10S is reduced to an ultra-high vacuum by operating an exhaust device (not shown) such as a vacuum pump or the like. A desired gas used for substrate processing is supplied into the processing chamber 10 through a gas supply line (not shown) communicating with a gas supply part (not shown).

The placing table 20 for placing the substrate W is disposed in the processing chamber 10. The placing table 20 is made of a material having high thermal conductivity (e.g., Cu). The placing table 20 includes an electrostatic chuck. The electrostatic chuck has an electrode 21 embedded in a dielectric film. A predetermined potential is applied to the electrode 21 through the slip ring 60 and the power supply rod 63, which will be described later. With this configuration, the substrate W can be attracted by the electrostatic chuck and fixed to the upper surface of the placing table 20. Further, a first comb-tooth structure 20a is formed on the bottom surface (first contact surface) of the placing table 20, which is opposite to the placing surface (upper surface) on which the substrate W is placed. The comb-tooth structure 20a has a plurality of annular protrusions protruding downward (toward a refrigeration medium 32) from the bottom surface (first contact surface) of the placing table 20, and recesses are formed between the protrusions. Further, circular and/or annular recesses and protrusions are alternately formed coaxially with a central axis CL of the placing table 20. In the example shown in FIGS. 1 and 2, a first annular protrusion and a second annular protrusion are provided radially outward from the center of the central axis CL, and a first circular recess formed at the inner side of the first protrusion, and a second annular recess formed between the first protrusion and the second protrusion are provided.

The freezing device 30 is disposed below the placing table 20. The freezing device 30 is formed by stacking a refrigerator 31 and a refrigeration medium 32. The refrigeration medium 32 may also be referred to as “cold link.” The refrigerator 31 holds the refrigeration medium 32 and cools the upper surface of the refrigeration medium 32 to an extremely low temperature. The refrigerator 31 preferably uses a Gifford-McMahon (GM) cycle in view of cooling performance. The refrigeration medium 32 is fixed on the refrigerator 31 and the upper portion thereof is accommodated in the processing chamber 10. The refrigeration medium 32 is made of a material having high thermal conductivity (e.g., Cu) or the like, and has a substantially cylindrical outer shape. The refrigeration medium 32 is disposed such that the center thereof coincides with the center axis CL of the placing table 20. Further, a second comb-tooth structure 32a is formed on the upper surface (second contact surface) of the refrigeration medium 32. The comb-tooth structure 32a has a plurality of annular recesses on the upper surface (second contact surface) of the refrigeration medium 32, and protrusions are formed between the recesses. Further, in the comb-tooth structure 32a, circular and/or annular protrusions and recesses are alternately formed coaxially with the central axis CL of the placing table 20. In the example shown in FIGS. 1 and 2, a third annular recess and a fourth annular recess are formed radially outward from the center of the central axis CL, and a fourth annular protrusion formed at the inner side of the third recess and a fourth annular protrusion formed between the third recess and the fourth recess are provided.

Further, the recess of the comb-tooth structure 32a is formed at a position corresponding to the protrusion of the comb-tooth structure 20a, and the recess of the comb-tooth structure 20a is formed at a position corresponding to the protrusion of the comb-tooth structure 32a. In other words, the third recess of the refrigeration medium 32 is formed at a position corresponding to the first protrusion of the placing table 20, the fourth recess of the refrigeration medium 32 is formed at a position corresponding to the second protrusion of the placing table 20. The first recess of the placing table 20 is formed at a position corresponding to a third protrusion of the refrigeration medium 32, and the second recess of the placing table 20 is formed at a position corresponding to a fourth protrusion of the refrigeration medium 32. Accordingly, the comb-tooth structure 20a and the comb-tooth structure 32a do not interfere with each other when the upper surface of the refrigeration medium 32 is pressed against the bottom surface of the placing table 20. In other words, when the bottom surface (first contact surface) of the placing table 20 and the upper surface (second contact surface) of the refrigeration medium 32 are brought into contact with each other, the protrusions of the comb-tooth structure 20a is inserted into the recesses of the comb-tooth structure 32a. Further, the comb-tooth structures 20a and 32a are formed coaxially with respect to the central axis CL. Hence, the comb-tooth structure 20a and the comb-tooth structure 32a do not interfere with each other during the rotation of the placing table 20.

Further, the height of the protrusion of the comb-tooth structure 20a formed on the bottom surface (first contact surface) of the placing table 20 may be less than the depth of the recess of the comb-tooth structure 32a formed on the upper surface (second contact surface) of the refrigeration medium 32.

Further, although the case in which the comb-tooth structure 20a has the plurality of annular protrusions protruding downward (toward the refrigeration medium 32) from the bottom surface (first contact surface) of the placing table 20 and the comb-tooth structure 32a has the plurality of annular recesses on the upper surface (second contact surface) of the refrigeration medium 32 has been described, the present disclosure is not limited thereto. The comb-tooth structure 20a may have a plurality of annular recesses on the bottom surface (first contact surface) of the placing table 20, and the comb-tooth structure 32a may have a plurality of annular protrusions protruding upward (toward the placing table 20) from the upper surface (second contact surface) of the refrigeration medium 32.

A heat conductive member 33 is disposed on the upper surface (second contact surface) of the refrigeration medium 32. In a state where the thermal contact between the placing table 20 and the freezing device 30 is released (see FIG. 1), the heat conductive member 33 is disposed on the upper surface of the refrigeration medium 32 of the freezing device 30. In a state where the placing table 20 and the freezing device 30 are thermally connected (see FIG. 2), the heat conductive member 33 is interposed between the bottom surface (first contact surface) of the placing table 20 and the upper surface (second contact surface) of the refrigeration medium 32 of the freezing device 30.

The heat conductive member 33 is made of a soft metal that is elastically deformable. In other words, the heat conductive member 33 is made of a soft metal that is more elastically deformable than the material of the bottom surface of the placing table 20 and/or the upper surface of the refrigeration medium 32. In other words, the heat conductive member 33 is made of a metal of which hardness (e.g., Vickers hardness) is less than that of the material of the bottom surface of the placing table 20 and/or the upper surface of the refrigeration medium 32. Further, the heat conductive member 33 is made of a material that can be used in the vacuum atmosphere of the inner space 10S and at an extremely low temperature cooled by the refrigerator 31. Further, the heat conductive member 33 is made of a material that does not affect the process of substrate processing. Moreover, the heat conductive member 33 is preferably made of a material having high thermal conductivity. The material of the heat conductive member 33 may be a material having thermal conductivity lower than that of the material of the bottom surface of the placing table 20 and/or the upper surface of the refrigeration medium 32. Specifically, the soft metal may be copper, indium, silver, tin, or the like. The heat conductive member 33 is formed as a sheet-shaped member (soft metal sheet, e.g., indium sheet, or the like). Accordingly, even if the heat conductive member 33 is made of a material having thermal conductivity lower than that of the material of the bottom surface of the placing table 20 and/or the upper surface of the refrigeration medium 32, the influence on the overall heat conduction from the refrigerator 31 to the placing table 20 can be sufficiently reduced by forming the heat conductive member 33 as a thin sheet-shaped member.

As shown in FIGS. 1 and 2, the heat conductive member 33 may be disposed to surround the comb-tooth structures 20a, 32a. In other words, the heat conductive member 33 may have an annular shape, and the comb-tooth structures 20a and 32a may be arranged at the radially inner side of the heat conductive member 33.

Further, the position where the heat conductive member 33 is provided is not limited thereto, and the heat conductive member may be provided on the upper surface of the protrusion of the comb-tooth structure 32a, or the heat conductive member may be provided on the bottom surface of the recess of the comb-tooth structure 32a.

The placing table 20 is rotatably supported by the rotation device 40. The rotation device 40 has a rotation driving device 41, a fixed shaft 45, a rotation shaft 44, a housing 46, magnetic fluid seals 47 and 48, and a stand 49.

The rotation driving device 41 is a direct drive motor having a rotor 42 and a stator 43. The rotor 42 has a substantially cylindrical shape extending coaxially with the rotation shaft 44, and is fixed to the rotation shaft 44. The stator 43 has a substantially cylindrical shape with an inner diameter greater than the outer diameter of the rotor 42. The rotation driving device 41 may be in a form other than a direct drive motor, and may be in a form including a servo motor and a transmission belt.

The rotation shaft 44 has a substantially cylindrical shape extending coaxially with the central axis CL of the placing table 20. The fixed shaft 45 is provided at the radially inner side of the rotation shaft 44. The fixed shaft 45 has a substantially cylindrical shape extending coaxially with the central axis CL of the placing table 20. The housing 46 is provided at the radially outer side of the rotation shaft 44. The housing 46 has a substantially cylindrical shape extending coaxially with the central axis CL of the placing table 20, and is fixed to the processing chamber 10.

The magnetic fluid seal 47 is provided between the outer circumferential surface of the fixed shaft 45 and the inner circumferential surface of the rotation shaft 44. The magnetic fluid seal 47 rotatably supports the rotation shaft 44 with respect to the fixed shaft 45, and seals the gap between the outer circumferential surface of the fixed shaft 45 and the inner circumferential surface of the rotation shaft 44 to separate a second space S2 (to be described later) from the external space of the processing chamber 10. The magnetic fluid seal 48 is provided between the inner circumferential surface of the housing 46 and the outer circumferential surface of the rotation shaft 44. The magnetic fluid seal 48 rotatably supports the rotation shaft 44 with respect to the housing 46, and seals the gap between the inner circumferential surface of the housing 46 and the outer circumferential surface of the rotation shaft 44 to separate the inner space 10S of the decompressible processing chamber 10 from the external space of the processing chamber 10. As a result, the rotation shaft 44 is rotatably supported by the fixed shaft 45 and the housing 46.

The refrigeration medium 32 is inserted into the radially inner side of the fixed shaft 45.

The stand 49 has a support member 49a and a locking member 49b.

The support member 49a is, e.g., a cylindrical member. The upper part of the support member 49a is fixed to the placing table 20. The lower part of the support member 49a is connected to the rotation shaft 44 via a bellows 82. Further, a rotational force transmission mechanism (not shown) that transmits the rotation of the rotation shaft 44 to the support member 49a while allowing the support member 49a to slide up and down with respect to the rotation shaft 44 is disposed between the rotation shaft 44 and the support member 49a. The rotational force transmission mechanism may have, for example, a hole portion formed at the support member 49a and a shaft portion standing upright from the rotation shaft 44, and may have a configuration in which the shaft portion is inserted into the hole portion. Further, the rotational force transmission mechanism has multiple (e.g., three) sets of the hole portion and the shaft portion in the circumferential direction of the support member 49a and the rotation shaft 44.

Therefore, by moving the support member 49a such that the shaft portion is inserted into the hole portion, the support member 49a slides downward with respect to the rotation shaft 44. Further, by moving the support member 49a such that the shaft portion is removed from the hole portion, the support member 49a slides upward with respect to the rotation shaft 44. Moreover, the rotation of the rotation shaft 44 is transmitted to the support member 49a via the shaft portion inserted into the hole portion. Further, the rotational force transmission mechanism has multiple (e.g., three) sets of the hole portion and the shaft portion in the circumferential direction of the support member 49a and the rotation shaft 44. Further, the rotational force transmission mechanism may be provided inside the bellows 82 or outside the bellows 82.

The locking member 49b is fixed to the housing 46.

Here, as shown in FIG. 2, when the refrigeration medium 32 is raised and pressed against the placing table 20, the support member 49a is locked by the locking member 49b. Further, when the refrigeration medium 32 is pressed against the placing table 20, the housing 46 fixed to the processing chamber 10 receives the load through the support member 49a and the locking member 49b. Accordingly, the rotation shaft 44 is prevented from tilting and being brought into contact with the fixed shaft 45 or the housing 46, and the deterioration of the sealing performance of the magnetic fluid seals 47 and 48 is prevented.

On the other hand, as shown in FIG. 1, when the refrigeration medium 32 is lowered and separated from the placing table 20, the support member 49a and the locking member 49b are also separated. With the above configuration, when the rotor 42 of the rotation driving device 41 rotates, the rotation shaft 44, the bellows 82, the support member 49a, and the placing table 20 rotate relative to the refrigeration medium 32.

The freezing device 30 is supported by the lifting device 50 to be movable up and down. The lifting device 50 has an air cylinder 51, a link mechanism 52, a freezing device support 53, a linear guide 54, a fixed portion 55, and a bellows 56.

The air cylinder 51 is a mechanical device whose rod moves linearly by air pressure. The link mechanism 52 converts the linear movement of the rod of the air cylinder 51 into vertical movement of the freezing device support 53. The link mechanism 52 has a lever structure, one end of which is connected to the air cylinder 51 and the other end of which is connected to the freezing device support 53. Accordingly, a large pressing force can be generated with a small thrust of the air cylinder 51. The freezing device support 53 supports the freezing device 30 (the refrigerator 31 and the refrigeration medium 32). The freezing device support 53 is guided in the vertical direction by the linear guide 54.

The fixed portion 55 is fixed to the bottom surface of the fixed shaft 45. The substantially cylindrical bellows 56 surrounding the refrigerator 31 is provided between the bottom surface of the fixed portion 55 and the upper surface of the freezing device support 53. The bellows 56 is a metal bellows structure that is vertically extensible/contractible. Accordingly, the fixed portion 55, the bellows 56, and the freezing device support 53 seal the gap between the inner circumferential surface of the fixed shaft 45 and the outer circumferential surface of the refrigeration medium 32.

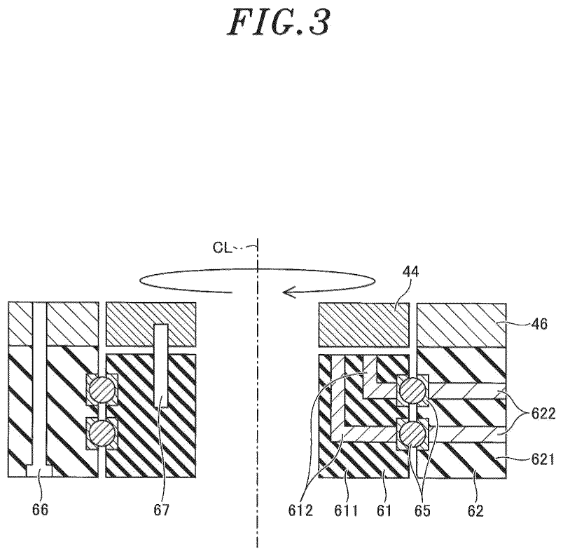

The slip ring 60 is provided below the rotation shaft 44 and the housing 46. The slip ring 60 has a rotating body 61 having a metal ring, and a fixed body 62 having a brush. The rotating body 61 has a substantially cylindrical shape extending coaxially with the rotation shaft 44, and is fixed to the bottom surface of the rotation shaft 44. The fixed body 62 has a substantially cylindrical shape with an inner diameter slightly greater than the outer diameter of the rotating body 61, and is fixed to the bottom surface of the housing 46. The slip ring 60 is electrically connected to a power supply (not shown), and supplies the power from the power supply to the power supply rod 63. With this configuration, it is possible to apply a potential from the power supply to the electrode 21 without twisting the power supply rod 63. The structure of the slip ring 60 is not limited, and may be, e.g., a brush structure, a contactless power supply structure, a mercury-free structure, or a structure containing conductive liquid, or the like. The slip ring 60 will be described in detail later with reference to FIG. 3.

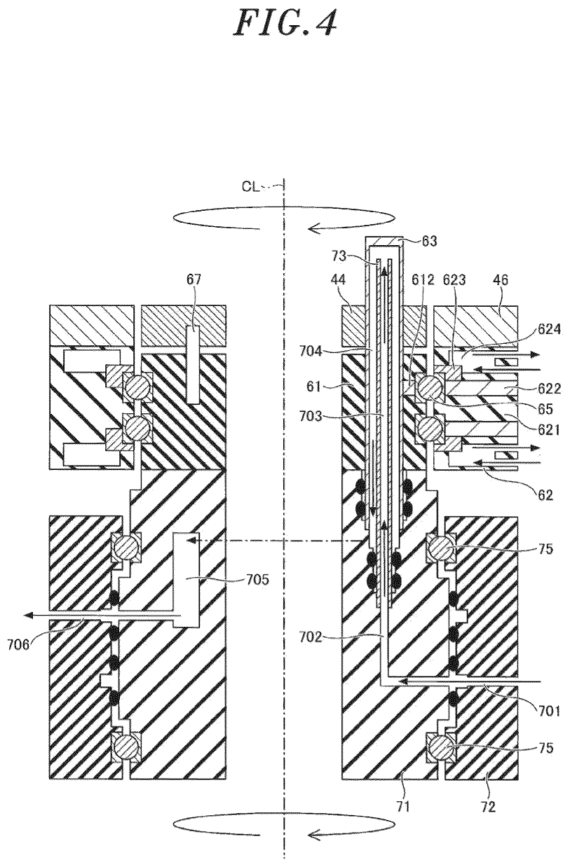

Further, the cooling mechanism 70 for supplying cooling water to the power supply rod 63 is disposed below the slip ring 60. The cooling mechanism 70 will be described in detail later with reference to FIG. 4.

The controller 90 is, e.g., a computer and includes a central processing unit (CPU), a random access memory (RAM), a read only memory (ROM), an auxiliary storage device, or the like. The CPU operates based on a program stored in the ROM or the auxiliary storage device, and controls the operation of the substrate processing apparatus 1. The controller 90 may be provided inside or outside the substrate processing apparatus 1. When the controller 90 is provided outside the substrate processing apparatus 1, the controller 90 can control the substrate processing apparatus 1 by a communication device such as a wired or wireless communication device.

In the case of performing desired processing on the substrate W, as shown in FIG. 1, the controller 90 controls the lifting device 50 (the air cylinder 51) to separate the placing table 20 from the refrigeration medium 32, and controls the rotation device 40 (the rotation driving device 41) to rotate the placing table 20 on which the substrate W is placed. Accordingly, the in-plane uniformity of the substrate processing (e.g., film formation or the like) of the substrate W can be improved.

In the case of cooling the placing table 20 and the substrate W placed on the placing table 20, as shown in FIG. 2, the controller 90 stops the rotation device 40 (the rotation driving device 41) to stop the rotation of the placing table 20, and controls the lifting device 50 (the air cylinder 51) to bring the placing table 20 into contact with the refrigeration medium 32. Accordingly, the substrate W placed on the placing table 20 can be cooled.

A substantially cylindrical bellows 81 (first bellows) is provided between the refrigeration medium 32 and the fixed shaft 45. The bellows 81 is a metal bellows structure that is extensible/contractible in the vertical direction (axial direction of the central axis CL). One end of the bellows 81 is airtightly fixed to the refrigeration medium 32 by welding, and the other end of the bellows 81 is airtightly fixed to the fixed shaft 45 by welding. Further, a substantially cylindrical bellows 82 (second bellows) is provided between the placing table 20 (the support member 49a fixed to the placing table 20) and the rotation shaft 44. The bellows 82 is a metal bellows structure that is extensible/contractible in the vertical direction (axial direction of the central axis CL). One end of the bellows 82 is airtightly fixed to the placing table 20 (the support member 49a fixed to the placing table 20) by welding, and the other end of the bellows 81 is airtightly fixed to the rotation shaft 44 by welding.

Here, a space isolated from the inner space 10S is formed on the back side of the placing table 20. Specifically, a first space S1 is formed between the bottom surface of the placing table 20 and the upper surface of the refrigeration medium 32. In addition, a second space S2 that is sealed by the bellows 81 and 82 and the magnetic fluid seal 47 is formed. In other words, a heat transfer gas supply space (the first space S1 and the second space S2) isolated from the inner space 10S is formed by the placing table 20, the refrigeration medium 32, the bellows 81 provided between the refrigeration medium 32 and the fixed shaft 45, the bellows 82 provided between the placing table 20 and the rotation shaft 44, and the magnetic fluid seal 47 provided between the outer circumferential surface of the fixed shaft 45 and the inner circumferential surface of the rotation shaft 44. In this manner, the heat transfer gas supply space (the first space S1 and the second space S2) is a space that includes the bottom surface (first contact surface) of the placing table 20 and the upper surface (second contact surface) of the refrigeration medium 32, and is isolated from the inner space 10S.

As shown in FIG. 1, when the placing table 20 is rotated, the first space S1 and the second space S2 communicate with each other. As shown in FIG. 2, when the refrigeration medium 32 is pressed against the placing table 20, the first space S1 and the second space S2 are isolated by the heat conductive member 33 provided at the contact portion between the refrigeration medium 32 and the placing table 20. Further, the first space S1 and the second space S2 may communicate with each other when the refrigeration medium 32 is pressed against the placing table 20.

A third space S3 sealed by the bellows 81 and 56 is formed. In other words, the third space S3 isolated from the inner space 10S is formed by the refrigeration medium 32, the cylindrical fixed shaft 45 and fixed portion 55, the freezing device support 53, the bellows 81 provided between the refrigeration medium 32 and the fixed shaft 45, and the bellows 56 provided between the fixed portion 55 and the freezing device support 53.

In this manner, the bellows 81 seals the gap between the first and second spaces S1 and S2 and the third space S3. The bellows 82 seals the gap between the first and second spaces S1 and S2 and the inner space 10S. The bellows 56 seals the gap between the third space S3 and the inner space 10S. The magnetic fluid seal 47 seals the gap between the first and second spaces S1 and S2 and the external space of the processing chamber 10. The magnetic fluid seal 48 seals the gap between the inner space 10S and the external space of the processing chamber 10.

Further, the freezing device 30 has a gas inlet port 83 that introduces a heat transfer gas into the first and second spaces S1 and S2. A heat transfer gas supply source (not shown) is connected to the gas inlet port 83. Accordingly, the heat transfer gas supply source fills the first space S1 and the second space S2 with the heat transfer gas through the gas inlet port 83. The heat transfer gas may be, e.g., He gas. A switching valve may be disposed in the path between the gas inlet port 83 and the heat transfer gas supply source, and may be switched to connect the gas inlet port 83 and an exhaust device (not shown). Accordingly, by switching the switching valve, a gas is exhausted from the first space S1 and the second space S2 through the gas inlet port 83, and the first space S1 and the second space S2 are depressurized to a vacuum atmosphere. Further, another switching valve may be provided in the path between the gas inlet port 83 and the heat transfer gas supply source, and may be switched to connect the gas inlet port 83 and the external space of the processing chamber 10. Accordingly, by switching another switching valve, the first space S1 and the second space S2 are opened to the atmosphere through the gas inlet port 83.

Further, an exhaust port 84 is disposed at the freezing device support 53. An exhaust device (not shown) is connected to the exhaust port 84. Accordingly, a gas is exhausted from the third space S3, and the third space S3 is depressurized to a vacuum atmosphere. In other words, the space between the freezing device 30 (the refrigerator 31 and the refrigeration medium 32) and the fixed shaft 45 and the fixed portion 55 is vacuum insulated. Further, a switching valve may be disposed in the path between the exhaust port 84 and the exhaust device, and may be switched to connect the exhaust port 84 and the external space of the processing chamber 10. By switching the switching valve, the third space S3 is opened to the atmosphere through the exhaust port 84.

With this configuration, as shown in FIG. 2, in a state where the rotation of the placing table 20 is stopped and the refrigeration medium 32 is in contact with the placing table 20, the placing table 20 is cooled mainly by contact heat transfer. Further, the contact heat transfer between the placing table 20 and the refrigeration medium 32 can be improved by providing the heat conductive member 33 therebetween. Further, heat is transferred between the placing table 20 and the refrigeration medium 32 via the heat transfer gas filled in the first space S1 formed by the upper and lower comb-tooth structures 20a and 32a. Here, by using the comb-tooth structures 20a and 32a, the surface area facing the first space S1 can be increased, and the heat transfer between the placing table 20 and the refrigeration medium 32 via the heat transfer gas can be improved.

Further, as shown in FIG. 1, in a state where the refrigeration medium 32 and the placing table 20 are separated and the placing table 20 is rotated, heat is transferred (gas heat transfer) from the placing table 20 to the refrigeration medium 32 via the heat transfer gas filled in the heat transfer gas supply space (the first space S1 and the second space S2). Accordingly, it is possible to suppress an increase in the temperature of the placing table 20 during the substrate processing in which the placing table 20 is rotated. Further, when the refrigeration medium 32 is brought into contact with the placing table 20 to cool the placing table 20 after the substrate processing, time for cooling by the contact can be shortened. Hence, the throughput of substrate processing in the substrate processing apparatus 1 can be improved.

Further, the heat transfer gas supply space (the first space S1 and the second space S2) is formed using the bellows 81 and 82, which are metal bellows structures that are vertically extensible/contractible. Accordingly, even if the bellows 81 and 82 are cooled via the placing table 20 and the refrigeration medium 32, which are cooled by the refrigerator 31, the deterioration of the sealing performance due to cooling contraction can be prevented compared to the case of using a seal member made of resin or the like. Further, by using the bellows 81 and 82, which are metal bellows structures, the replacement frequency can be reduced compared to the case of using a seal member made of resin or the like, and the downtime of the substrate processing apparatus 1 can be suppressed.

Next, the slip ring 60 will be described with reference to FIG. 3. FIG. 3 is an example of a cross-sectional view of the slip ring 60.

The slip ring 60 has a rotating body 61 that is fixed to the bottom surface of the rotation shaft 44 and rotates together with the rotation shaft 44, and a fixed body 62 fixed to the bottom surface of the housing 46. A conductive bearing 65 is provided between the rotating body 61 and the fixed body 62. The conductive bearing 65 has a rolling body, an inner ring, and an outer ring. The rolling body, the inner ring, and the outer ring are made of a conductive material such as a metal or the like, and the inner ring and the outer ring are electrically connected via the rolling body. Further, the rolling body may be coated with conductive grease. The rotating body 61 has an insulating part 611 such as resin or the like, and a conductive part 612. The conductive part 612 is electrically connected with the inner ring of the conductive bearing 65. The fixed body 62 has an insulating part 621 such as resin or the like, and a conductive part 622. The conductive part 622 is electrically connected with the outer ring of the conductive bearing 65. With this configuration, the conductive part 622 of the fixed body 62 and the conductive part 612 of the rotating body 61 are electrically connected via the conductive bearing 65.

Here, if the rotating body 61 is fastened to the mounting surface (bottom surface) of the rotation shaft 44 with bolts and the fixed body 62 is fastened to the mounting surface (bottom surface) of the housing 46 with bolts, axial misalignment may occur between the rotating body 61 and the fixed body 62 of the slip ring 60 due to the height difference between the mounting surface (bottom surface) of the rotation shaft 44 and the mounting surface (bottom surface) of the housing 46. Due to the axial misalignment between the rotating body 61 and the fixed body 62, a load may be generated at the conductive bearing 65, which may shorten the lifetime of the conductive bearing 65 or may cause damages to the conductive bearing 65. Since the load is generated at the conductive bearing 65, neighboring driving parts may be affected due to poor electrical connection or scattering of wear particles.

In the slip ring 60 of the present embodiment, the fixed body 62 is fastened to the mounting surface (bottom surface) of the housing 46 with a bolt 66. In other words, the rotational position and the axial position of the fixed body 62 are fixed with respect to the housing 46. On the other hand, the rotating body 61 is not fixed to the mounting surface (bottom surface) of the rotation shaft 44, but is maintained in a floating state by the conductive bearing 65.

A hole is formed in each of the mounting surface (bottom surface) of the rotation shaft 44 and the mounting surface (upper surface) of the rotating body 61. One end of a driven pin 67 is formed in the mounting surface (bottom surface) of the rotation shaft 44 and inserted into a hole extending in a direction parallel to the central axis CL, and the other end of the driven pin 67 is formed in the mounting surface (upper surface) of the rotating body 61 and inserted into a hole extending in a direction parallel to the central axis CL. In a state where the mounting surface (bottom surface) of the rotation shaft 44 and the mounting surface (upper surface) of the rotating body 61 are separated from each other, the rotation of the rotation shaft 44 is transmitted to the rotating body 61 via the driven pin 67. In this manner, in the slip ring 60 of the present embodiment, the fixed body 62 is fastened to the mounting surface (bottom surface) of the housing 46 with the bolt 66. Due to the hole formed in the rotor 61 of the slip ring 60 and the driven pin 67 and the hole formed in the rotation shaft 44, the rotational position of the rotor 61 relative to the rotation shaft 44 is fixed, and the axial position of the rotor 61 relative to the rotation shaft 44 is not restricted. In other words, the driven pin 67 connects the rotation shaft 44 and the rotor 61. With respect to the rotation shaft 44, the rotational position of the rotating body is fixed, but the axial position thereof is not restricted. Further, it is preferable that the driven pins 67 are arranged at three locations on the same circumference at equal intervals. Accordingly, the axial runout of the slip ring 60 is suppressed.

Further, the height position (axial position) of the mounting surface (upper surface) of the fixed body 62 is higher than the height position (axial position) of the mounting surface (upper surface) of the rotor 61. Accordingly, the generation of the load at the conductive bearing 65 can be prevented even if the mounting surface (bottom surface) of the rotation shaft 44 is lower than the mounting surface (bottom surface) of the housing 46.

Next, the structure for cooling the power supply rod 63 and the conductive bearing 65 will be described with reference to FIG. 4. FIG. 4 is an example of a cross-sectional view explaining the structure for cooling the power supply rod 63 and the conductive bearing 65.

For example, when a high-frequency power is applied to the electrode 21 to produce plasma in the inner space 10S and attract ions from the generated plasma to the substrate W placed on the placing table 20, heat is generated at the conducting portion. In other words, heat is generated at the power supply rod 63 or the conductive bearing 65.

The fixed body 62 has a heat medium channel 624 through which a heat transfer medium (e.g., cooling water, cooling gas, or the like) flows. Further, the fixed body 62 has a heat transfer member 623 that is exposed to the heat medium channel 624 and is in contact with the outer ring of the conductive bearing 65. The heat transfer member 623 is made of a material having high thermal conductivity such as a metal or the like. Accordingly, the conductive bearing 65 can be cooled via the heat transfer member 623.

The power supply rod 63 has a hollow structure. The cooling mechanism 70 has a rotor 71 that is fixed to the rotor 61 of the slip ring 60 and rotates together with the rotation shaft 44, and a fixed body 72 that is fixed to the housing 46. A bearing 75 and a seal member are provided between the rotor 71 and the fixed body 72.

The heat transfer medium (e.g., cooling water, cooling gas, or the like) supplied to the heat medium channel 701 of the fixed body 72 flows into the heat medium channel 702 of the rotor 71, and flows through the heat medium channel 703 inside the inner tube 73 inserted into the hollow power supply rod 63. Further, the power supply rod 63 is cooled by supplying a heat transfer medium to the heat medium channel 704 between the hollow power supply rod 63 and the outside of the inner tube 73. The heat transfer medium that has cooled the power supply rod 63 flows through the heat medium channel 705 of the rotating body 71 and the heat medium channel 706 of the fixed body 72.

In this manner, the power supply rod 63 is cooled by supplying a heat transfer medium into the hollow power supply rod 63. Accordingly, the heat generated by the power supply rod 63 is prevented from being transferred to the placing table 20 or the freezing device 30.

While the substrate processing apparatus 1 has been described, the present disclosure is not limited to the above-described embodiment, and various modifications and improvements can be made within the scope of the gist of the present disclosure described in the claims.

1. A substrate processing apparatus comprising:
a processing chamber;
a placing table disposed in the processing chamber and having a first contact surface on an opposite side to a placing surface on which a substrate is placed;
a freezing device having a second contact surface and configured to cool the placing table;
a rotation device configured to rotate the placing table;
a lifting device configured to raise and lower the freezing device to bring the first contact surface and the second contact surface into contact with each other or separate the first contact surface and the second contact surface from each other;
a heat transfer gas supply space including the first contact surface of the placing table and the second contact surface of the freezing device and isolated from an inner space of the processing chamber; and
a gas inlet port that supplies a heat transfer gas to the heat transfer gas supply space.

2. The substrate processing apparatus of claim 1, further comprising:
a rotation shaft rotated by the rotating device;
a fixed shaft provided at a radially inner side of the rotation shaft;
a first bellows disposed between the freezing device and the fixed shaft;
a second bellows disposed between the placing table and the rotation shaft; and
a magnetic fluid seal disposed between an outer circumferential surface of the fixed shaft and an inner circumferential surface of the rotation shaft,
wherein the heat transfer gas supply space is formed by the first contact surface, the second contact surface, the first bellows, the second bellows, and the magnetic fluid seal.

3. The substrate processing apparatus of claim 2, wherein the first bellows and the second bellows are metal bellows structures that are extensible and contractible.

4. The substrate processing apparatus of claim 1, wherein the first contact surface and the second contact surface have a comb-tooth structure.

5. The substrate processing apparatus of claim 4, wherein the first contact surface has a plurality of annular protrusions,
the second contact surface has a plurality of annular recesses, and
when the first contact surface and the second contact surface are brought into contact with each other, the protrusions of the first contact surface are inserted into the recesses of the second contact surface.

6. The substrate processing apparatus of claim 1, further comprising:
a heat conductive member interposed between the first contact surface and the second contact surface,
wherein the heat conductive member is made of a soft metal that is softer than a material of the first contact surface and/or a material of the second contact surface.

7. The substrate processing apparatus of claim 1, further comprising:
a rotation shaft rotated by the rotating device;
a housing provided at a radially outer side of the rotation shaft; and
a slip ring,
wherein the slip ring has:
a fixed body fastened to the housing by a bolt and having a fixed rotational position and a fixed axial position relative to the housing;
a rotating body connected to the rotation shaft by a driven pin and having a fixed rotational position relative to the rotation shaft; and
a bearing provided between the rotating body and the fixed body.

8. The substrate processing apparatus of claim 7, further comprising:
a power supply rod that supplies a power to an electrode of the placing table,
wherein the power supply rod has a hollow structure through which a heat transfer medium is supplied.
